(19) United States
(12) Patent Application Publication
(10) Pub. No.: US 2006/0260676 A1
(43) Pub. Date: Nov. 23, 2006

(54) Photodetector

(76) Inventors: Fei Gao, Singapore (SG); CheeWee Liu, (US); Sungjoo Lee, Singapore (SG); Dim-Lee Kwong, Austin, TX (US)

Correspondence Address: CHRISTIE, PARKER & HALE, LLP, PO BOX 7068, PASADENA, CA, 91109-7068, US

(21) Appl. No.: 11/438,077

(22) Filed: May 18, 2006

Related U.S. Application Data
(60) Provisional application No. 60/681,970, filed on May 18, 2005.

(51) Int. Cl. H01L 31/00

(52) U.S. Cl. 136/252

(57) ABSTRACT

A photodetector and a method of manufacturing the photodetector are provided. The photodetector comprises a first semiconductor layer; a dielectric layer formed on the first semiconductor layer, the dielectric layer comprising a plurality of openings; a second semiconductor layer formed on the dielectric layer, such that portions of the second semiconductor layer are in contact with the first semiconductor layer at the openings; wherein regions of structural disorder with dislocations exist at interfaces between the first and second semiconductor layers at the openings.

### CROSS-REFERENCE TO RELATED APPLICATION (S)

This application claims the benefit and priority of U.S. Provisional Patent Application No. 60/681,970, filed May 18, 2005, the disclosure of which is hereby incorporated by reference herein.

### FIELD OF THE INVENTION

The invention relates broadly to a photodetector and to a method of fabricating a photodetector.

### BACKGROUND

Photodetectors are suitably doped semiconductor devices that have the PN junction reverse biased below the breakdown voltage. When the photodetector is exposed to light of a certain wavelength, electron-hole pairs will be generated due to light absorption at the PN junction. The generated electron-hole pairs will then be transported to form a photocurrent under the applied electric field.

Typical materials used in photodetectors are indium gallium arsenide (InGaAs), indium phosphate (InP) and gallium arsenide (GaAs) which are generally grown by Molecular Beam Epitaxy (MBE) or Ultra-high-Vacuum-Chemical-Vapor-Deposition (UHVCVD).

Most long wavelength photodetectors use an InP substrate. However InP is expensive and fragile. Further, material compatibility problems arise when integrating InP based photodetectors into silicon based Complimentary Metal Oxide Semiconductor (CMOS) systems.

In other photodetectors that employ germanium grown on a silicon substrate, the slow carriers generated in the silicon layer slows down the response time of the photodetector. To minimise the photocurrent being generated from the slow carriers from germanium-silicon photodetectors, time consuming cyclic annealing or depositing of buffer layers is used to minimise dislocations arising from the lattice structure mismatch between germanium and silicon.

There is thus a need to provide a photodetector that addresses one or more of the above limitations.

### SUMMARY OF THE INVENTION

According to a first aspect of the invention, there is provided a photodetector comprising a first semiconductor layer; a dielectric layer formed on the first semiconductor layer, the dielectric layer comprising a plurality of openings; a second semiconductor layer formed on the dielectric layer, such that portions of the second semiconductor layer are in contact with the first semiconductor layer at the openings; wherein regions of structural disorder with dislocations exist at interfaces between the first and second semiconductor layers at the openings.

The photodetector may further comprise a tunnel dielectric layer formed on the second semiconductor layer.

The photodetector may further comprise an array of first electrodes formed on the tunnel dielectric layer, and a second electrode formed on a back surface of the first semiconductor layer.

The first semiconductor layer may comprise a single crystal semiconductor substrate.

The single crystal semiconductor substrate may comprise single crystal silicon.

The dielectric layer may comprise an insulator layer of a semiconductor-on-insulator substrate, and the first semiconductor layer may comprise a semiconductor bulk of the semiconductor-on-insulator substrate.

The semiconductor-on-insulator substrate may comprise germanium on insulator, silicon on semiconductor, or silicon germanium on insulator.

The second semiconductor layer may comprise germanium, silicon, silicon germanium, III-V semiconductor compounds, or II-VI semiconductor compounds.

According to another aspect of the invention, there is provided a method of fabricating a photodetector, the method comprising the steps of: providing a first semiconductor layer; providing a dielectric layer formed on the first semiconductor layer, the dielectric layer comprising a plurality of openings; providing a second semiconductor layer formed on the dielectric layer, such that portions of the second semiconductor layer are in contact with the first semiconductor layer at the openings; and forming regions of structural disorder with dislocations at interfaces between the first and second semiconductor layers at the openings.

The first semiconductor layer may be provided in the form of a single crystal wafer. The dielectric layer may be provided in the form of an insulator layer of a semiconductor-on-insulator substrate, the first semiconductor layer may be provided in the form of a semiconductor bulk of the semiconductor-on-insulator substrate, and the method may further comprise removing a top semiconductor layer of the semiconductor-on-insulator substrate before, during, or after a formation of the openings in the dielectric layer.

### BRIEF DESCRIPTION OF THE DRAWINGS

This present invention is now be described by way of non-limiting examples, with reference to the accompanying drawings, in which:

FIG. 1 shows a schematic cross sectional view of a portion of a photodetector according to an embodiment of the present invention.

FIGS. 2 to 8 show schematic cross sectional views illustrating the various stages employed to fabricate the photodetector of FIG. 1.

FIG. 9 shows a schematic top view of a portion of the photodetector of FIG. 1.

FIG. 10 shows plots of light absorption coefficient (cm⁻¹) and penetration depth (μm) against wavelength (μm) of light for various semiconductor materials.

FIGS. 11 and 12 show schematic cross sectional views illustrating two initial stages employed to fabricate a photodetector according to an alternative embodiment of the present invention.

FIG. 13 shows a schematic cross sectional view of a portion of a photodetector according to an alternative embodiment of the present invention.

### DESCRIPTION OF EMBODIMENTS OF THE INVENTION

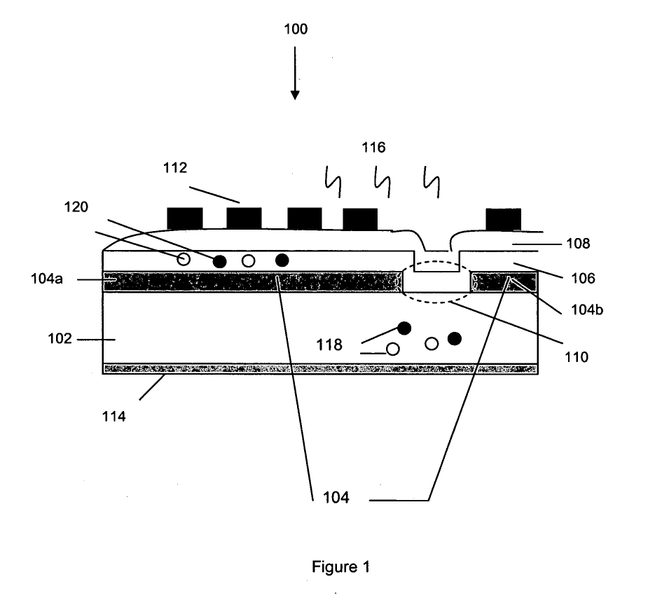

FIG. 1 shows a detail of a cross sectional view of a photodetector 100 fabricated in accordance with one embodiment of the present invention.

The photodetector 100 comprises a semiconductor substrate 102. Formed substantially across an upper surface 101 of the semiconductor substrate 102 is a first dielectric layer 104. Openings 110 are formed in the first dielectric layer 104 so that the first dielectric layer 104 is divided into segments 104a and 104b. Only one opening 110 is shown in the detailed view in FIG. 1, with an array of openings 110 being formed across the photodetector 100. A semiconductor layer 106 is formed on the first dielectric layer 104 such that portions of the semiconductor layer 106 are in contact with the semiconductor substrate 102 through the openings 110. Only one strip of the semiconductor layer 106 is shown in the detailed view in FIG. 1, with strips of the semiconductor layer 106 being formed across the photodetector 100. There are depressions at the portions of the semiconductor layer 106 which are above the openings 110. A second dielectric layer 108 is formed on the semiconductor layer 106 such that there are also depressions at the portions of the second dielectric layer 108 which are above the openings 110. An array of metal contacts 112 is disposed on the second dielectric layer 108. Formed across a back surface of the semiconductor substrate 102 is a metal layer 114.

In the embodiment shown in FIG. 1, the thickness of the semiconductor substrate 102 is about 600 μm to about 800 μm. The first dielectric layer 104 is about 100 nm thick, while the thickness of the semiconductor layer 106 is about 100 nm. The second dielectric layer 108 is about 100 nm thick.

In the embodiment shown in FIG. 1, crystalline silicon is used for the semiconductor substrate 102, while crystalline germanium is used for the semiconductor layer 106.

As germanium and silicon are structurally different, a lattice mismatch occurs at the silicon-germanium interface at the openings 110. This structural mismatch causes structural disorder in the region of the openings 110, with dislocations acting to form carrier recombination centers where slow speed electron-hole pairs recombine. On the other hand, for the remainder of the semiconductor layer 106 formed above the first dielectric layer 104 as a structural buffer layer, there is no lattice mismatch region created.

In the embodiment shown in FIG. 1, SiO₂ is used for the first dielectric layer 104. The second dielectric layer 108 is a thin layer of SiO₂, the thin layer allowing the tunneling of carriers through the second dielectric layer 108 to reach the array of metal contacts 112. Aluminum is used for the metal contacts 112 and the metal layer 114.

In operation, the photodetector 100 is reverse biased by applying a biasing voltage across the metal contacts 112 and the metal layer 114. An electric field is thus established across the photodetector 100.

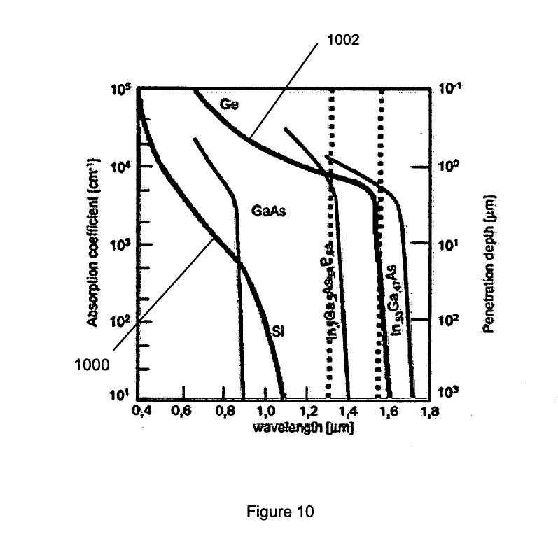

When light 116 of a certain wavelength is incident on the photodetector 100, electron-hole pairs 118 and 120 will respectively be formed in both the semiconductor substrate 102 and the semiconductor layer 106. In this embodiment, as the semiconductor substrate 102 is formed from silicon while the semiconductor layer 106 is formed from germanium, the electron-hole pairs 118 formed in the semiconductor substrate 102 are slower than the electron-hole pairs formed 120 in the semiconductor layer 106. This is because germanium has a higher light absorption coefficient especially when germanium is exposed to light of a high wavelength, as evidenced from a comparison of graphs 1000 and 1002 shown in FIG. 10.

Due to structural disorder present at the openings 110, the slower electron-hole pairs 118 recombine at dislocations acting as recombination centers. However, the faster electron-hole pairs 120 will not recombine at the seed region. The faster holes will penetrate the seed region 111 and be attracted towards the negatively biased metal layer 114 while the faster electrons will be attracted towards the positively biased array of metal contacts 112. The faster electrons will then tunnel through the second dielectric layer 108 to reach the array of metal contacts 112. In this manner, a carrier channel is established across the photodetector 100 and a photocurrent is thus formed.

Thus, unlike conventional photodetectors that seek to minimise dislocations caused by the lattice mismatch at a germanium-silicon interface by either time consuming cyclic annealing or depositing continuous buffer layers, the above approach takes advantage of the dislocations to prevent the forming of photocurrent from slow carriers. At the same time, the active region responsible for effecting the photocurrent is nearly dislocation free.

Further, in conventional photodetectors where germanium is directly grown on silicon, the slow carriers formed within the silicon layer contribute to the photocurrent generated and therefore slow down the response time of conventional photodetectors.

In contrast, portions of the germanium layer 106 are isolated from the silicon substrate 102 through the use of the dielectric layer 104. The photodetector 100 achieved thus has a faster response time as the generated photocurrent is predominantly from the faster charge carriers generated within the germanium layer 106.

Furthermore, the use of the intrinsic physical property of germanium having a high light absorption, especially for high wavelength light, to achieve a photodetector with a fast response time, large bandwidth and a high photocurrent output also contrasts with conventional photodetectors that seek to increase the absorption properties of silicon by adding complex resonant cavities.

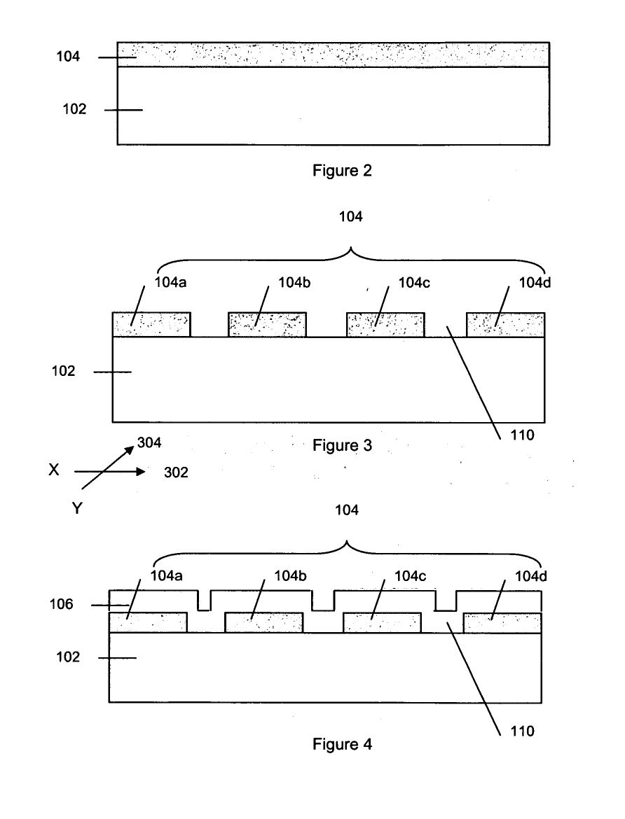

FIGS. 2 to 8 show cross sectional views of the various stages employed to fabricate the photodetector 100 shown in FIG. 1. The same numerals used in FIG. 1 have been used to indicate the same layers in FIGS. 2 to 8.

In FIG. 2, the semiconductor substrate 102 is first cleaned in a wet chemical such as dilute HF followed by depositing or growing the first dielectric layer 104 on the upper surface of the semiconductor substrate 102. The semiconductor substrate 102 can be any single crystal semiconductor material. A silicon single crystal substrate is used in the embodiment shown in FIG. 1. Deposited or thermally grown SiO₂ is used for the first dielectric layer 104.

After the first dielectric layer 104 is deposited, a pattern defining the array of the openings 110 is transferred onto the substrate 102 employing lithography through a mask (not shown). Portions of the first dielectric layer 104 are then removed in FIG. 3 to form the array of openings 110 in accordance with the pattern. The openings 110 are spaced a distance of about 30 μm along an X-axis direction 302 and a distance of about 1.5 μm to about 2 μm along a Y-axis direction 304. The openings 110 have an area of about 1 μm² to about 4 μm².

The openings 110 expose portions of the underlying semiconductor substrate 102. The selective removal of the first dielectric layer 104 portions is performed through etching techniques such as wet chemical etching using Buffered Oxide Etching. After the selective removal, the first dielectric layer 104 is divided into various segments 104a, 104b, 104c and 104d.

The semiconductor layer 106 is then deposited such that the semiconductor layer 106 is in contact with both the first dielectric layer 104 and the exposed portions of the semiconductor substrate 102 through the openings 110 as shown in FIG. 4. Depressions occur at the portions of the semiconductor layer 106 which correspond to the areas above the openings 110. The various deposition techniques that can be used to deposit the semiconductor layer 106 include but are not limited to Chemical Vapour Deposition (CVD), Physical Vapour Deposition (PVD) and Jet Vapor Deposition.

A pattern defining strips of the semiconductor layer 106 is transferred onto the semiconductor layer 106 employing lithography through a mask (not shown) and subsequent etching techniques such as wet chemical etching using Buffered Oxide Etching. With reference to FIG. 9, the mask is aligned such that each strip e.g. 106a of the semiconductor layer 106 is aligned with one row of the array of openings 110.

In the embodiment shown in FIG. 4, germanium is used for the semiconductor layer 106. In other embodiments, germanium may be replaced by other semiconductor materials such as silicon, silicon germanium, III-V semiconductor compounds, or II-VI semiconductor compounds.

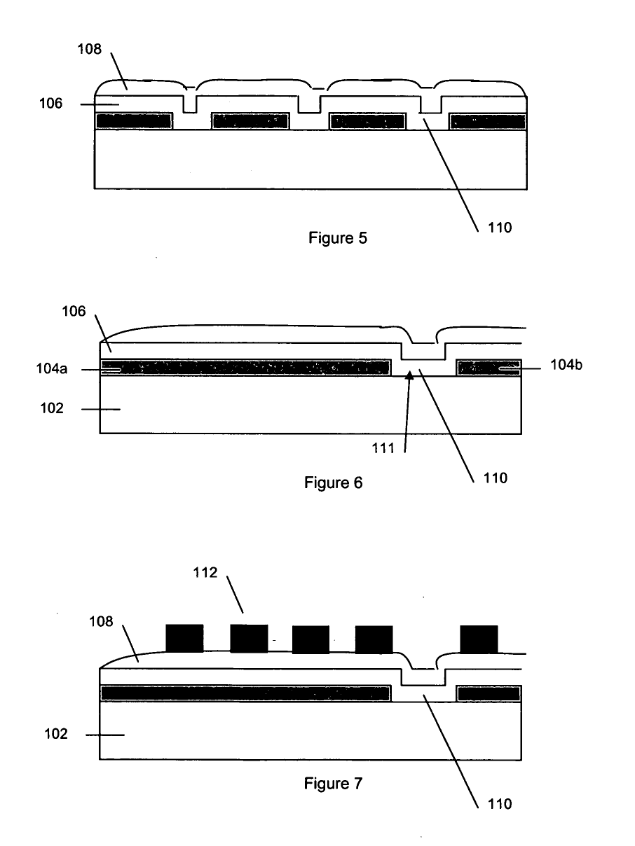

In FIG. 5, the second dielectric layer 108 is deposited on the substrate structure including the strips of the semiconductor layer 106. While the second dielectric layer 108 may be patterned according to the strips of the semiconductor layer 106, it will be appreciated that patterning is optional, resulting in a less complex manufacturing process.

Depressions occur at the portions of the second dielectric layer 108 which correspond to the areas above the openings 110. The deposition techniques that can be used to deposit the second dielectric layer 108 include but are not limited to CVD, PVD and Atomic-Layer Deposition (ALD). The second dielectric layer 108 is relatively thin so as to allow the tunneling of charge carriers when the photodetector 100 (FIG. 1) is operated. In the embodiment shown in FIG. 1, SiO₂ is used for the second dielectric layer 108. The resulting semiconductor structure then undergoes thermal annealing as illustrated in FIG. 6.

FIG. 6 shows a detail of FIG. 5 during the subsequent annealing step. It will be appreciated that the first dielectric segments 104a and 104b have been chosen arbitrarily to illustrate the annealing process. Annealing is done at a temperature that is preferably around the melting point of the semiconductor layer 106. However, the annealing temperature can also be either higher or lower than the melting point of the semiconductor layer 106. In the embodiment shown in FIG. 1 where germanium is used for the semiconductor layer 106, the annealing temperature is around 800° C. to around 900° C. The annealing time is around two hours. During this annealing stage, cyclic annealing can be employed where the annealing temperature is varied between two temperatures of around 700° C. to around 900° C. During the annealing, the germanium semiconductor layer 106 will change from an amorphous structure into a single crystalline structure starting from the region defined by the opening 110 which acts as a seed region 111. The crystalline structure change propagates from the seed region 111 across the entire semiconductor layer 106.

Structural disorder with dislocations occur at the interface between the germanium semiconductor layer 106 and the silicon semiconductor substrate 102 at the seed region because of the lattice mismatch between silicon and germanium. However, the remainder of the semiconductor layer 106 above the first dielectric segments 104a and 104b as a structural buffer layer remains dislocation free.

A metal layer (not shown) is then deposited above the second dielectric layer 108. The metal layer is then patterned to form a desired structure through the application of a suitable mask. As shown in FIG. 7, the metal layer is patterned to form the array of metal contacts 112 and aluminum is used for the array of metal contacts 112 in the example embodiment.

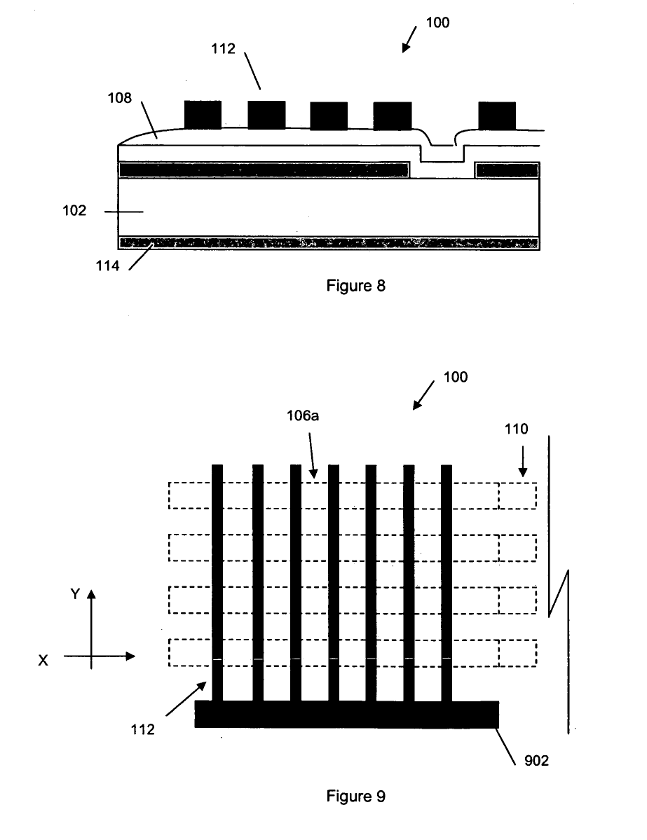

With reference to FIG. 8, the metal layer 114 is deposited on the back surface of the semiconductor substrate 102. In the embodiment, the material used for the metal layer 114 is the same as the material used for the array of metal contacts 112, i.e. aluminum.

FIG. 9 shows a schematic top view of the photodetector 100. (FIG. 1). FIG. 9 illustrates that the array of metal contacts 112 are connected at one end to a terminal 902. The terminal 902 is connected to an electrical port (not shown) which can be connected to external devices so that the external devices can tap the photocurrent generated by the photodetector 100.

In different embodiments, any single crystal semiconductor material can be used for the semiconductor substrate 102. SiNₓ or Al₂O₃ can be used for the first dielectric layer 104. SiO₂, SiNₓ, HfO₂ and other kinds of dielectric film can be used for the second dielectric layer 108. Co, Fe, Cr, Mn, Nb, Ru, Ta, Ti, V, W, Zr or any alloy metals such as such as TaN, TiN can be used for the metal contacts 112 and the metal layer 114. In other embodiments, the material used for the metal contacts 112 and for the metal layer 114 may be different.

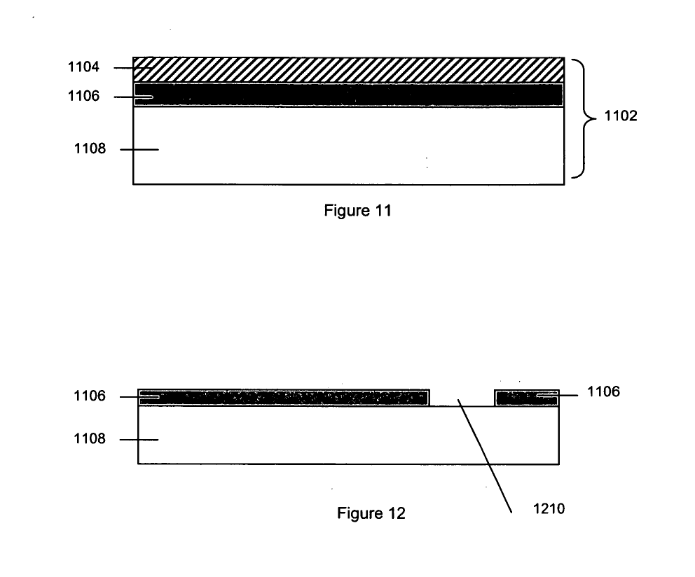

An alternative embodiment will now be described with reference to FIGS. 11 to 13, in which a silicon on insulator substrate 1102 (FIG. 11) is used instead of the semiconductor substrate 102 (FIG. 1).

The silicon top layer 1104 is removed and openings 1210 are formed in the oxide layer 1106 through to the bulk silicon 1108, as shown in FIG. 12. The silicon top layer 1104 can be removed before, after or during the formation of the openings 1210, using known techniques such as etching techniques. Known lithography techniques can be used to form the openings 1210. Only one opening 1210 is shown in the detailed view in FIG. 12, with an array of openings 1210 being formed across the photodetector 1200. After formation of the openings 1210, the remaining process steps can be as described above from FIGS. 4 to 8.

It is noted that the duration and temperature of the annealing that occurs at the step described above with reference to FIG. 6 advantageously is not long enough for silicon from the bulk silicon 1108 to diffuse into the germanium semiconductor layer 106. Furthermore, the sidewalls of the openings 1210 facilitate confinement of dislocations at the openings 1210. Thus, the structural disorder with dislocations remains at the interface between the germanium semiconductor layer 106 and the bulk silicon 1108 at the openings 1210.

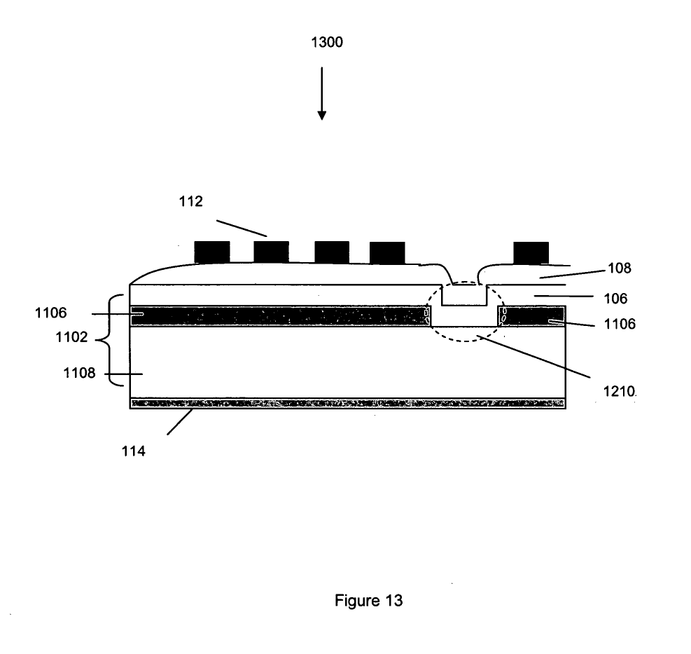

FIG. 13 shows a schematic cross-sectional view of a portion of the resulting photodetector 1300. In this embodiment, it will be appreciated that the oxide layer 1106 of the silicon substrate 1102 provides the first dielectric layer (compare layer 104 in FIG. 1), while the bulk silicon 1108 provides the first semiconductor layer (compare 102 in FIG. 1).

In alternative embodiments, germanium on insulator, and silicon germanium on insulator can be used for the semiconductor substrate 102.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A photodetector comprising
a first semiconductor layer;
a dielectric layer formed on the first semiconductor layer, the dielectric layer comprising a plurality of openings;
a second semiconductor layer formed on the dielectric layer, such that portions of the second semiconductor layer are in contact with the first semiconductor layer at the openings;
wherein regions of structural disorder with dislocations exist at interfaces between the first and second semiconductor layers at the openings.

2. The photodetector as claimed in claim 1, further comprising a tunnel dielectric layer formed on the second semiconductor layer.

3. The photodetector as claimed in claim 2, further comprising an array of first electrodes formed on the tunnel dielectric layer, and a second electrode formed on a back surface of the first semiconductor layer.

4. The photodetector as claimed in any one of the preceding claims, wherein the first semiconductor layer comprises a single crystal semiconductor substrate.

5. The photodetector as claimed in claim 4, wherein the single crystal semiconductor substrate comprises single crystal silicon.

6. The photodetector as claimed in claim 1, wherein the dielectric layer comprises an insulator layer of a semiconductor-on-insulator substrate, and the first semiconductor layer comprises a semiconductor bulk of the semiconductor-on-insulator substrate.

7. The photodetector as claimed in claim 6, wherein the semiconductor-on-insulator substrate comprises germanium on insulator, silicon on semiconductor, or silicon germanium on insulator.

8. The photodetector as claimed in claim 1, wherein the second semiconductor layer comprises germanium, silicon, silicon germanium, III-V semiconductor compounds, or II-VI semiconductor compounds.

9. A method of fabricating a photodetector, the method comprising the steps of:
providing a first semiconductor layer;
providing a dielectric layer formed on the first semiconductor layer, the dielectric layer comprising a plurality of openings;
providing a second semiconductor layer formed on the dielectric layer, such that portions of the second semiconductor layer are in contact with the first semiconductor layer at the openings; and
forming regions of structural disorder with dislocations at interfaces between the first and second semiconductor layers at the openings.

10. The method as claimed in claim 9, wherein the first semiconductor layer is provided in the form of a single crystal wafer.

11. The method as claimed in claim 9, wherein the dielectric layer is provided in the form of an insulator layer of a semiconductor-on-insulator substrate, the first semiconductor layer is provided in the form of a semiconductor bulk of the semiconductor-on-insulator substrate, and the method further comprises removing a top semiconductor layer of the semiconductor-on-insulator substrate before, during, or after a formation of the openings in the dielectric layer.
